(19) United States
(12) Patent Application Publication
(10) Pub. No.: US 2014/0015068 A1
(43) Pub. Date: Jan. 16, 2014

(54) Gate Structure, Semiconductor Device and Methods for Forming the Same

(71) Applicants: Hong Yang, Beijing (CN); Wenwu Wang, Beijing (CN); Huaxiang Yin, Beijing (CN); Jiang Yan, Newburgh, MD (US); Xueli Ma, Beijing (CN)

(72) Inventors: Hong Yang, Beijing (CN); Wenwu Wang, Beijing (CN); Huaxiang Yin, Beijing (CN); Jiang Yan, Newburgh, MD (US); Xueli Ma, Beijing (CN)

(21) Appl. No.: 13/699,731

(22) PCT Filed: Jul. 24, 2012
(86) PCT No.: PCT/CN12/79091

§ 371 Date: Nov. 25, 2012

(30) Foreign Application Priority Data
Jul. 16, 2012 (CN) 201210246111.1

(51) Int. Cl. H01L 29/49; H01L 21/28

(52) U.S. Cl. CPC H01L 29/495; H01L 21/28008; H01L 29/4966
USPC 257/412; 438/585; 257/288

(57) ABSTRACT

The disclosure relates to a gate structure, a semiconductor device and methods for forming the same. An embodiment of the disclosure provides a method for forming a gate structure, including: providing a substrate; forming an interface layer on the substrate; forming a gate dielectric layer on the interface layer; forming a gate dielectric capping layer on the gate dielectric layer; forming an etching stop layer on the gate dielectric capping layer; forming an oxygen scavenging element layer on the etching stop layer; forming an oxygen scavenging element capping layer on the oxygen scavenging element layer; performing Post-Metallization Annealing; performing etching until the etching stop layer is exposed; forming a work function adjustment layer on the etching stop layer; and forming a gate layer on the work function adjustment layer.

This application is the national phase application of International Application No. PCT/CN2012/079091, entitled “GATE STRUCTURE, SEMICONDUCTOR DEVICE AND METHODS FOR FORMING THE SAME,” filed on Jul. 24, 2012, which claims priority to Chinese Patent Application No. 201210246111.1, entitled “GATE STRUCTURE, SEMICONDUCTOR DEVICE AND METHODS FOR FORMING THE SAME,” filed on Jul. 16, 2012. Both of the Chinese and PCT applications are incorporated herein by reference in their entireties.

### FIELD OF THE INVENTION

The disclosure relates to the field of semiconductor technology, and particularly to a gate structure, a semiconductor device and methods for forming the same.

### BACKGROUND OF THE INVENTION

With rapid development of semiconductor technology, feature sizes of Complementary Metal-Oxide-Semiconductor (CMOS) devices in very large scale integrated circuits are constantly reducing as predicted by Moore Law, and traditional polysilicon gates and silicon dioxide gate dielectrics are facing many technical challenges. For example, starting from the 45 nm technology node and beyond, the silicon dioxide gate dielectric layer has a thickness of several atomic layers, which will incur sharp rises of gate leakage current and power consumption. In addition, the polysilicon gate electrode causes a polysilicon depletion effect and problems such as a too high gate resistance and the like. To this end, high dielectric constant (high-k) gate dielectric and metal gate electrode, which may be introduced to effectively solve these problems associated with CMOS devices, have been successfully applied to the 32 nm technology by Intel Corporation, USA.

However, introduction of high-k gate dielectric/metal gate structure brings some new problems. For example, during the growth of high-k gate dielectric, a silicon dioxide interface inevitably exists between the high-k gate dielectric and the surface of semiconductor substrate. Generally, the interface layer in the high-k gate dielectric/metal gate process has a thickness of about 0.5 to 0.7 nm. However, once CMOS devices enter the 32 nm technology node or beyond, the equivalent gate oxide thickness of the high-k gate dielectric is not more than 0.7 nm or even highly-demanded, and the thickness of the interface layer will be increased during a high temperature annealing in the subsequent process. Therefore, it becomes a difficulty and focus in the art to reduce equivalent oxide thickness of the high-k gate dielectric by optimizing process conditions and/or materials.

### SUMMARY OF THE INVENTION

In view of the above problems, the present invention provides a new method for manufacturing a Metal-Oxide Semiconductor Field Effect Transistor (MOSFET), which can effectively reduce the equivalent gate oxide thickness.

According to an embodiment of the disclosure, there is provided a method for forming a gate structure, including:

providing a substrate;

forming an interface layer on the substrate;

forming a gate dielectric layer on the interface layer;

forming a gate dielectric capping layer on the gate dielectric layer;

forming an etching stop layer on the gate dielectric capping layer;

forming an oxygen scavenging element layer on the etching stop layer;

forming an oxygen scavenging element capping layer on the oxygen scavenging element layer;

performing Post-Metallization Annealing (PMA);

performing etching until the etching stop layer is exposed;

forming a work function adjustment layer on the etching stop layer; and

forming a gate layer on the work function adjustment layer.

According to an embodiment of the disclosure, there is provided a method for forming a semiconductor device, including:

providing a substrate; and

forming a gate structure on the substrate by using the above mentioned method.

According to an embodiment of the disclosure, there is provided a gate structure, including:

an interface layer formed on a substrate;

a gate dielectric layer formed on the interface layer;

a gate dielectric capping layer formed on the gate dielectric layer;

an etching stop layer formed on the gate dielectric capping layer;

a work function adjustment layer formed on the etching stop layer; and

a gate layer formed on the work function adjustment layer.

According to and embodiment of the disclosure, there is provided a semiconductor device including the above mentioned gate structure.

According to the method for forming the gate structure provided by the embodiment of the disclosure, by introducing an oxygen scavenging element layer above the gate dielectric layer, outside oxygen is prevented from entering the interface layer below the gate dielectric layer and oxygen in the interface layer is scavenged during the subsequent PMA process, thus the equivalent gate oxide thickness is effectively reduced. In addition, the influence on the equivalent work function of the metal gate by the oxygen scavenging element layer can be avoided by removing the oxygen scavenging element layer after realizing the reduction of the equivalent gate oxide thickness, thereby avoiding the problem that the adjustment of the equivalent work function would become a difficulty due to the introduction of the oxygen scavenging element.

In addition, the method for forming the gate structure provided by the embodiment of the disclosure is compatible with the mainstream MOSFET manufacturing methods and CMOS integrating methods, possesses good process stability and repeatability, and can be applied to large-scale production.

### BRIEF DESCRIPTION OF THE DRAWINGS

The above and other objects, features and advantages will become clear with reference to descriptions of the embodiments of the disclosure in conjunction with drawings. Throughout the drawings, same or similar reference numerals indicate same or similar structures or steps.

FIGS. 1 to 8 are schematic diagrams showing intermediate structures in the method for forming a gate structure according to an embodiment of the disclosure.

### DETAILED DESCRIPTION OF THE INVENTION

It is studied that “oxygen scavenging process” is one of effective approaches for reducing equivalent oxide thickness of high-k gate dielectric. The main principle is that Gibbs free energy of certain metals or other unsaturated oxygenated dielectric materials is much larger than that of the semiconductor substrate, i.e. oxides of these metals or saturated oxygenates of the unsaturated oxygenated dielectrics are more stable and easier to be formed than the oxide of the semiconductor substrate. Therefore, some metal films or other unsaturated oxygenated dielectric films can be added into the gate dielectric structure, and by means of a high temperature annealing process, the oxygen element in the interface layer between the high-k gate dielectric and the semiconductor substrate can be scavenged away, so that the interface layer is thinned or even eliminated, thus reducing the equivalent gate oxide thickness of the gate dielectric layer.

However, due to the introduction of the oxygen scavenging process, the oxygen scavenging element may enter the high-k gate dielectric layer, which leads to over-high gate leakage current. Moreover, the introduction of the oxygen scavenging element will bring a problem that the adjustment of the equivalent work function of the metal gate would become a difficulty. For example, the equivalent work function of the metal gate would drift in an opposite direction.

According to the method for forming the gate structure provided by the embodiment of the disclosure, by introducing an oxygen scavenging element layer above the gate dielectric layer, outside oxygen is prevented from entering the interface layer below the gate dielectric layer and oxygen in the interface layer is scavenged during the subsequent PMA process, thus the equivalent gate oxide thickness is effectively reduced. In addition, removing the oxygen scavenging element layer through etching after the PMA process may prevent the oxygen scavenging element layer from influencing the equivalent work function of the metal gate, thereby avoiding the problem that the adjustment of the equivalent work function would become a difficulty due to the introduction of the oxygen scavenging element.

Specific embodiments of the invention are described hereinafter in conjunction with the drawings.

To facilitate the sufficient understanding of the invention, many details are set forth in the following description. However, the present invention may be implemented in other manners than those described herein, and similar extensions can be made by those skilled in the art without deviating from the scope of the present invention. Therefore the present invention is not limited to the embodiments disclosed hereinafter.

When describing the embodiments of the present invention, for convenience of illustration, sectional views showing the structure of the device are enlarged partially and are not drawn to scale. The drawings are exemplary and are not intended to limit the protection scope of the invention.

It should be noted that the reference in the structures or steps that a first feature is “on” or “above” a second feature includes the case that the first and the second features are in direct contact and the case that additional features are present between the first and the second features, i.e., the first and the second feature may be not in direct contact.

According to an embodiment of the disclosure, there is provided a gate structure, including:

an interface layer formed on the substrate;

a gate dielectric layer formed on the interface layer;

a gate dielectric capping layer formed on the gate dielectric layer;

an etching stop layer formed on the gate dielectric capping layer;

a work function adjustment layer formed on the etching stop layer; and

a gate layer formed on the work function adjustment layer.

According to another embodiment of the disclosure, there is provided a semiconductor device including the above described gate structure.

For better understanding to the structure of the semiconductor device, methods for forming the above described gate structure and semiconductor device are further provided in embodiments of the disclosure. It should be noted that the following steps are only schematic and should not constitute limitations on the invention.

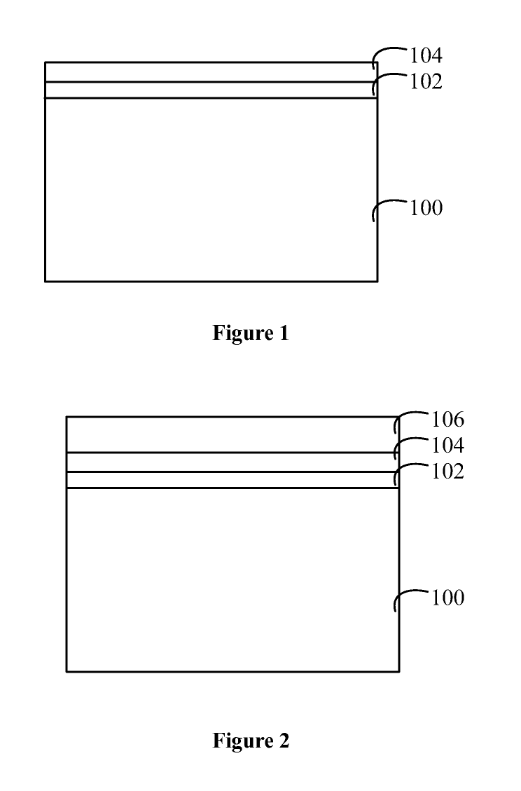

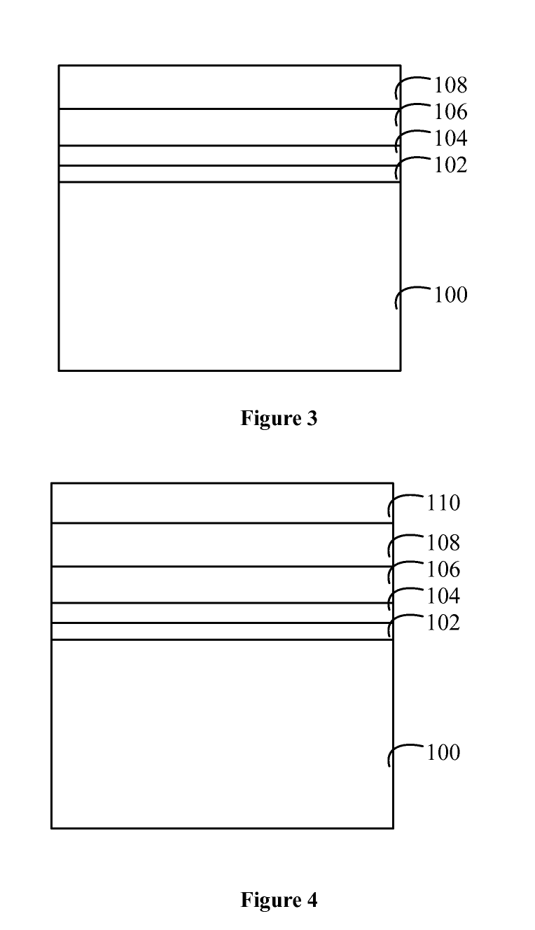

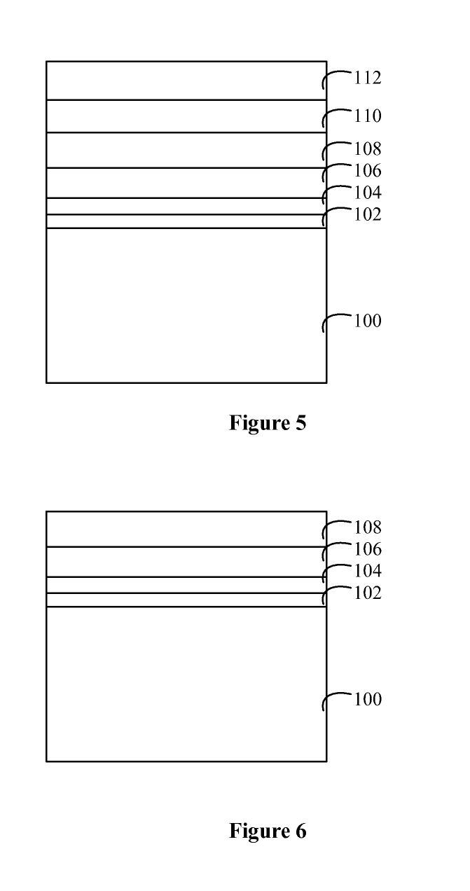

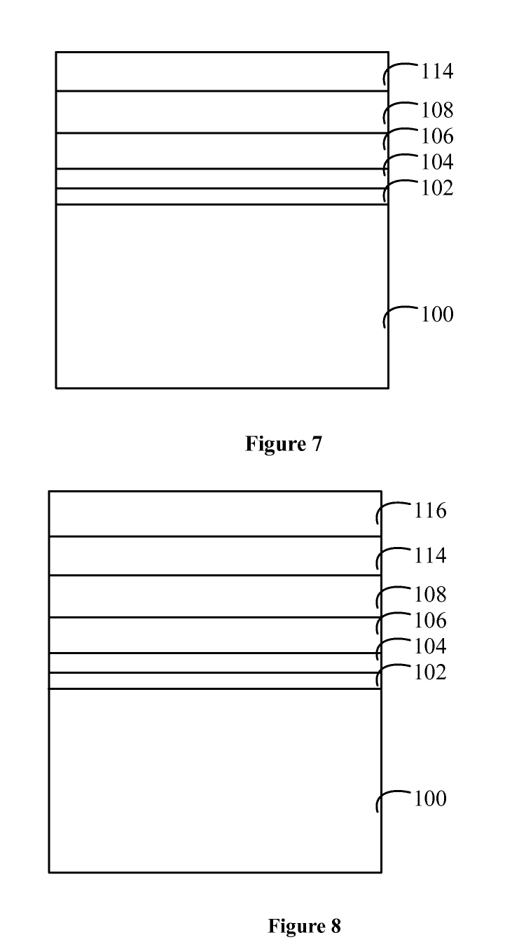

FIGS. 1 to 8 show a method for forming the gate structure according to one embodiment of the disclosure. The method includes the following steps.

Step S1: providing a substrate 100.

Step S2: forming an interface layer 102 on the substrate 100.

Optionally, the material of the interface layer 102 is silicon oxide (SiO2), and the thickness of the interface layer 102 is about 5 Å to 1 nm.

Step S3: forming a gate dielectric layer 104 on the interface layer 102.

Optionally, the material of the gate dielectric layer 104 is hafnium oxide (HfO2), and the thickness of the gate dielectric layer 104 is about 15 Å to 40 Å.

Step S4: forming a gate dielectric capping layer 106 on the gate dielectric layer 104.

Optionally, the material of the gate dielectric capping layer 106 is titanium nitride (TiN), and the thickness of the gate dielectric capping layer 106 is about 1 nm to 3 nm.

Step S5: forming an etching stop layer 108 on the gate dielectric capping layer 106.

Optionally, the material of the etching stop layer 108 is tantalum nitride (TaN), and the thickness of the etching stop layer 108 is about 1 nm to 8 nm.

Step S6: forming an oxygen scavenging element layer 110 on the etching stop layer 108.

Optionally, the material of the oxygen scavenging element layer 110 is titanium (Ti), and the thickness of the oxygen scavenging element layer 110 is about 5 Å to 5 nm.

Step S7: forming an oxygen scavenging element capping layer 112 on the oxygen scavenging element layer 110.

Optionally, the material of the oxygen scavenging element capping layer 112 is titanium nitride (TiN), and the thickness of the oxygen scavenging element capping layer 112 is about 1 nm to 8 nm.

Step S8: performing PMA.

Optionally, the temperature for the PMA is 300° C. to 1000° C., and the duration of the PMA is 5 seconds to 10 minutes.

Step S9: performing etching until the etching stop layer 108 is exposed.

Step S10: forming a work function adjustment layer 114 on the etching stop layer 108.

Optionally, the material of the work function adjustment layer 114 is titanium nitride (TiN) or titanium aluminum alloy (TiAl), and the thickness of the work function adjustment layer 114 is about 2 nm to 20 nm.

Step S11: forming a gate layer 116 on the work function adjustment layer 114.

Optionally, the material of the gate layer 116 is one of aluminum (Al), tungsten (W) and TiAl or a combination thereof, and the thickness of the gate layer 116 is about 5 nm to 20 nm.

At this point, the gate structure and corresponding semiconductor device formed according to the embodiments of the invention are obtained.

Although the embodiments of the disclosure have been described in detail with reference to the drawings, it should be understood by those skilled in the art that the above embodiments are only for illustration and do not constitute limitations on the invention. It should also be understood by those skilled in the art that numerous variations, alternatives and modifications can be made to the embodiments without departing from the scope defined by the claims. Therefore, the scope of the invention is only defined by the claims and the equivalents thereof

1. A method for forming a gate structure, comprising:
providing a substrate;
forming an interface layer on the substrate;
forming a gate dielectric layer on the interface layer;
forming a gate dielectric capping layer on the gate dielectric layer;
forming an etching stop layer on the gate dielectric capping layer;
forming an oxygen scavenging element layer on the etching stop layer;
forming an oxygen scavenging element capping layer on the oxygen scavenging element layer;
performing Post-Metallization Annealing;
performing etching until the etching stop layer is exposed;
forming a work function adjustment layer on the etching stop layer; and
forming a gate layer on the work function adjustment layer.

2. The method according to claim 1, wherein the gate dielectric capping layer comprises a material of TiN, and has a thickness of 1 nm to 3 nm.

3. The method according to claim 1, wherein the etching stop layer comprises a material of TaN, and has a thickness of 1 nm to 8 nm.

4. The method according to claim 1, wherein the oxygen scavenging element layer comprises a material of Ti, and has a thickness of 5 Å to 5 nm.

5. The method according to claim 1, wherein the oxygen scavenging element capping layer comprises a material of TiN, and has a thickness of 1 nm to 8 nm.

6. The method according to claim 1, wherein the PMA is performed under a temperature of 300 to 1000, and lasts for a duration of 5 seconds to 10 minutes.

7. The method according to claim 1, wherein the work function adjustment layer comprises a material of TiN or TiAl, and has a thickness of 2 nm to 20 nm.

8. The method according to claim 1, wherein the gate layer comprises a material of one of Al, W, TiAl or a combination thereof, and has a thickness of 5 nm to 20 nm.

9. A method for forming a semiconductor device, comprising:
providing a substrate; and
forming a gate structure of the semiconductor device on the substrate, comprising:
forming an interface layer on the substrate;
forming a gate dielectric layer on the interface layer;
forming a gate dielectric capping layer on the gate dielectric layer;
forming an etching stop layer on the gate dielectric capping layer;
forming an oxygen scavenging element layer on the etching stop layer;
forming an oxygen scavenging element capping layer on the oxygen scavenging element layer;
performing Post-Metallization Annealing;
performing etching until the etching stop layer is exposed;
forming a work function adjustment layer on the etching stop layer; and
forming a gate layer on the work function adjustment layer.

10. A gate structure, comprising:
an interface layer formed on a substrate;
a gate dielectric layer formed on the interface layer;
a gate dielectric capping layer formed on the gate dielectric layer;
an etching stop layer formed on the gate dielectric capping layer;
a work function adjustment layer formed on the etching stop layer; and
a gate layer formed on the work function adjustment layer.

11. The gate structure according to claim 10, wherein the gate dielectric capping layer comprises a material of TiN, and has a thickness of 1 nm to 3 nm.

12. The gate structure according to claim 10, wherein the etching stop layer comprises a material of TaN, and has a thickness of 1 nm to 8 nm.

13. The gate structure according to claim 10, wherein the work function adjustment layer comprises a material of TiN or TiAl, and has a thickness of 2 nm to 20 nm.

14. The gate structure according to claim 10, wherein the gate layer comprises a material of Al, W, TiAl or a combination thereof, and has a thickness of 5 nm to 20 nm.

15. A semiconductor device comprising a gate structure, wherein the gate structure comprises:
an interface layer formed on a substrate;
a gate dielectric layer formed on the interface layer;
a gate dielectric capping layer formed on the gate dielectric layer;
an etching stop layer formed on the gate dielectric capping layer;
a work function adjustment layer formed on the etching stop layer; and
a gate layer formed on the work function adjustment layer.

16. The method according to claim 9, wherein the gate dielectric capping layer comprises a material of TiN, and has a thickness of 1 nm to 3 nm.

17. The method according to claim 9, wherein the etching stop layer comprises a material of TaN, and has a thickness of 1 nm to 8 nm.

18. The method according to claim 9, wherein the oxygen scavenging element layer comprises a material of Ti, and has a thickness of 5 Å to 5 nm.

19. The method according to claim 9, wherein the oxygen scavenging element capping layer comprises a material of TiN, and has a thickness of 1 nm to 8 nm.

20. The method according to claim 9, wherein the PMA is performed under a temperature of 300 to 1000, and lasts for a duration of 5 seconds to 10 minutes.

21. The method according to claim 9, wherein the work function adjustment layer comprises a material of TiN or TiAl, and has a thickness of 2 nm to 20 nm.

22. The method according to claim 9, wherein the gate layer comprises a material of one of Al, W, TiAl or a combination thereof, and has a thickness of 5 nm to 20 nm.
